(19) United States
(12) Patent Application Publication
(10) Pub. No.: US 2010/0147558 A1
(43) Pub. Date: Jun. 17, 2010

(54) Anchor pin lead frame

(76) Inventor: Harry Pon, Portland, OR (US)

Correspondence Address: INTEL CORPORATION;c/o CPA Global, P.O. BOX 52050, MINNEAPOLIS, MN, 55402, US

(21) Appl. No.: 12/316,532

(22) Filed: Dec. 12, 2008

(51) Int. Cl. H05K 1/02; H05K 3/34

(52) U.S. Cl. 174/250; 29/840

(57) ABSTRACT

In some embodiments, a surface mount component includes a housing and one or more leads extending from the housing, wherein the one or more leads define respective voids through respective ends of the one or more leads. For example, the one or more leads may define a through-hole at respective ends of the one or more leads. For example, the fixing material may include solder. For example, the solder may form a pin which helps secure the surface mount component to the printed circuit board. Other embodiments are disclosed and claimed.

The invention relates to component packages. More particularly, some embodiments of the invention relate to surface mount component packages.

### BACKGROUND AND RELATED ART

Many electronic devices may include surface mount components. Surface mount components may be attached to a printed circuit board by soldering the leads of the surface mount component to pads on the surface of the printed circuit board. Solder joints may be subject to failure. For example, cracks in the solder joint may create electrical opens and/or component lifting and possibly pop off.

### BRIEF DESCRIPTION OF THE DRAWINGS

Various features of the invention will be apparent from the following description of preferred embodiments as illustrated in the accompanying drawings, in which like reference numerals generally refer to the same parts throughout the drawings. The drawings are not necessarily to scale, the emphasis instead being placed upon illustrating the principles of the invention.

FIG. 1 is a schematic representation of an electronic system in accordance with some embodiments of the invention.

FIG. 2 is a fragmented, sectional representation of the electronic system of FIG. 1.

FIG. 3 is a perspective view of a lead frame foot landing in accordance with some embodiments of the invention.

FIG. 4 is a schematic representation of a lead frame footing in accordance with some embodiments of the invention.

FIG. 5 is a schematic representation of another lead frame footing in accordance with some embodiments of the invention.

FIG. 6 is a schematic representation of a surface mount component in accordance with some embodiments of the invention.

FIG. 7 is a schematic representation of another surface mount component in accordance with some embodiments of the invention.

FIG. 8 is a perspective representation of another surface mount component in accordance with some embodiments of the invention.

FIG. 9 is a schematic representation of another surface mount component in accordance with some embodiments of the invention.

FIG. 10 is a schematic representation of another surface mount component in accordance with some embodiments of the invention.

FIG. 11 is a schematic representation of another surface mount component in accordance with some embodiments of the invention.

FIG. 12 is a schematic representation of another surface mount component in accordance with some embodiments of the invention.

FIG. 13 is a schematic representation of another surface mount component in accordance with some embodiments of the invention.

FIG. 14 is a schematic representation of another surface mount component in accordance with some embodiments of the invention.

FIG. 15 is a schematic representation of another surface mount component in accordance with some embodiments of the invention.

FIG. 16 is a schematic representation of another surface mount component in accordance with some embodiments of the invention.

FIG. 17 is a schematic representation of another surface mount component in accordance with some embodiments of the invention.

FIG. 18 is a schematic representation of another surface mount component in accordance with some embodiments of the invention.

FIG. 19 is a schematic representation of another surface mount component in accordance with some embodiments of the invention.

FIG. 20 is a schematic representation of another surface mount component in accordance with some embodiments of the invention.

FIG. 21 is a flow diagram in accordance with some embodiments of the invention.

FIG. 22 is another flow diagram in accordance with some embodiments of the invention.

FIG. 23 is another flow diagram in accordance with some embodiments of the invention.

### DESCRIPTION

In the following description, for purposes of explanation and not limitation, specific details are set forth such as particular structures, architectures, interfaces, techniques, etc. in order to provide a thorough understanding of the various aspects of the invention. However, it will be apparent to those skilled in the art having the benefit of the present disclosure that the various aspects of the invention may be practiced in other examples that depart from these specific details. In certain instances, descriptions of well known devices, circuits, and methods are omitted so as not to obscure the description of the present invention with unnecessary detail.

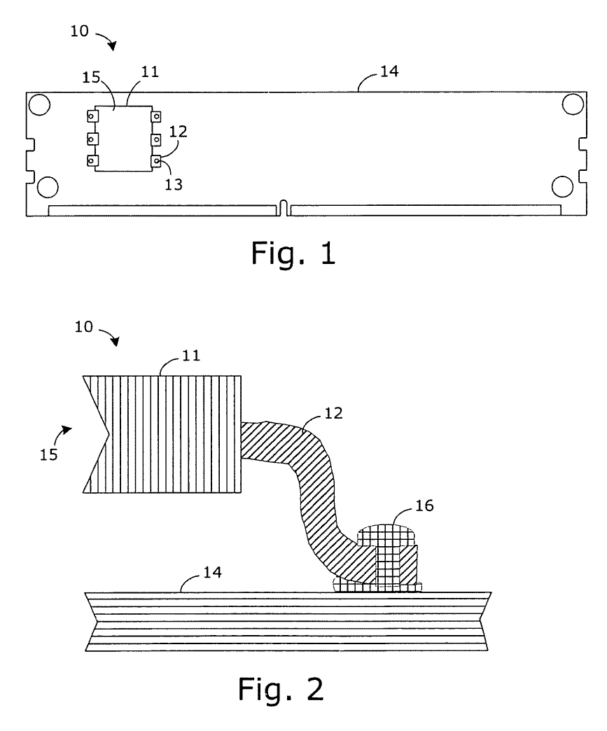

With reference to FIGS. 1 and 2, an electronic system 10 in accordance with some embodiments of the invention may include a printed circuit board 14 and a surface mount component 15 mounted on the printed circuit board. For example, the surface mount component 15 may include a housing 11 and one or more leads 12 extending from the housing 11, wherein the one or more leads 12 define respective voids 13 through respective ends of the one or more leads 12. The electronic system 10 may further include a fixing material 16 disposed through the respective voids 13 of the one or more leads 12 to secure the surface mount component 15 to the printed circuit board 14.

For example, the fixing material may include solder. For example, the solder may form a pin which helps secure the surface mount component to the printed circuit board. For example, the fixing material may include a conductive epoxy. For example, the fixing material may include a conductive silver epoxy. The particulars of the fixing material are not critical. Accordingly, any now known or hereinafter discovered material suitable for a making conductive bond between the leads and the printed circuit board may be utilized as the fixing material.

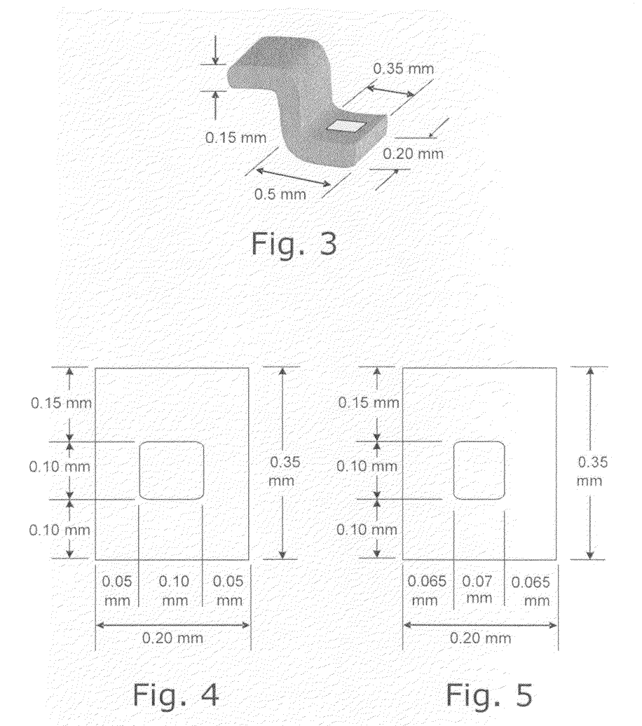

With reference to FIG. 3, a perspective view of a lead frame in accordance with some embodiments of the invention includes example dimensions. With reference to FIG. 4, a schematic representation of a lead frame foot landing in accordance with some embodiments of the invention includes example dimensions. With reference to FIG. 5, a schematic representation of another lead frame footing in accordance with some embodiments of the invention includes example dimensions.

Without being limited to theory of operation, it is believed that some embodiments of the invention may provide advantages in connection with solder joint reliability and/or bond strength. For example, an opening or hole in the foot of a package lead frame may accommodate a self forming pinning anchor rivet when the component is wave soldered on to a printed circuit board (PCB, e.g. a motherboard). For example, the pin or rivet may be formed by the solder over the lead frame footing. For example, the opening in the lead frame footing may allow the solder to flow through the lead frame opening to create a pinning anchor rivet which may provide additional strength to the solder joint. Advantageously, for example in connection with small form factor devices, additional strength in the solder joint may help the PCB and surface mount component withstand the expansion and contraction of temperature cycling stresses during qualification and/or under actual use conditions. Without being limited to theory of operation, it is believed that each opening in each of lead frame feet may have an additive and/or multiplicative strengthening effect to the whole component.

For example, in some embodiments of the electronic system 10 the one or more leads 12 may define a through-hole 13 at respective ends of the one or more leads 12. For example, in some embodiments of the electronic system 10, the one or more leads may include at least a first lead defining a first through hole having a first shape which is longer along a first axis of the first shape as compared to a second axis of the first shape, and a second lead defining a second through hole having a second shape which is longer along a first axis of the second shape as compared to a second axis of the second shape, wherein the first axis of the first shape is transverse to the first axis of the second shape. For example, in some embodiments of the electronic system 10, the one or more leads may define a plurality of through-holes at respective ends of the one or more leads.

For example, in some embodiments of the electronic system 10 the one or more leads 12 may define a notch at respective ends of the one or more leads. For example, in some embodiments of the electronic system 10, the one or more leads may include at least a first lead defining a first notch having a first position which is along an first edge of the first lead, and a second lead on a same side of the surface mount component as the first lead, the second lead defining a second notch having a second position which is along a different edge of the second lead as compared to the first edge of the first lead. For example, in some embodiments of the electronic system 10, the one or more leads define a plurality of notches at respective ends of the one or more leads.

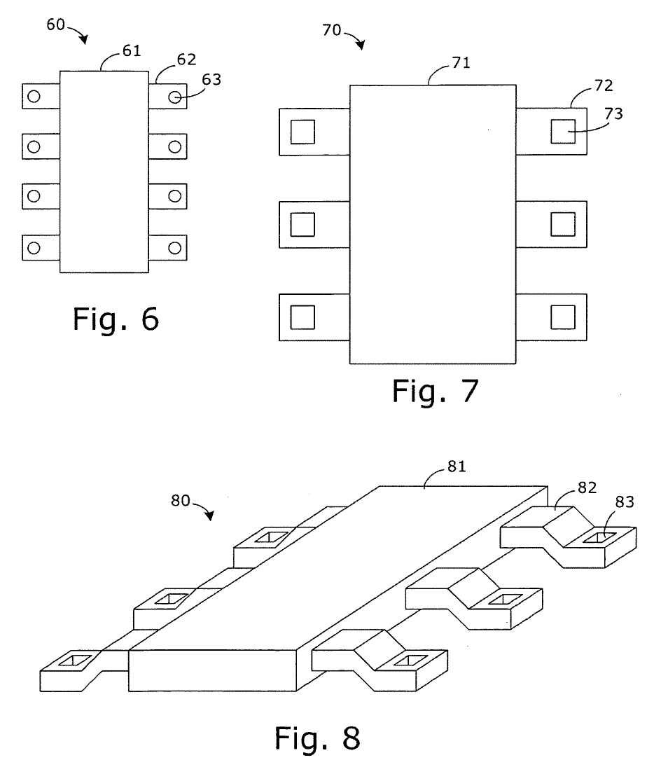

With reference to FIG. 6, a surface mount component 60 may include a housing 61 and one or more leads 62 extending from the housing. The one or more leads 62 may define respective voids 63 through respective ends of the one or more leads 62. For example, the one or more leads 62 may define a through-hole 63 at respective ends of the one or more leads 62. For example, a round hole 63 may be drilled through each of the leads 62.

With reference to FIG. 7, a surface mount component 70 may include a housing 71 and one or more leads 72 extending from the housing. The one or more leads 72 may define respective voids 73 through respective ends of the one or more leads 72. For example, the one or more leads 72 may define a through-hole 73 at respective ends of the one or more leads 72. For example, a square hole 73 may be punched through each of the leads 72.

With reference to FIG. 8, a surface mount component 80 may include a housing 81 and one or more leads 82 extending from the housing. The one or more leads 82 may define respective voids 83 through respective ends of the one or more leads 82. For example, the one or more leads 82 may define a through-hole 83 at respective ends of the one or more leads 82. For example, a rectangular hole 83 may be punched through each of the leads 82.

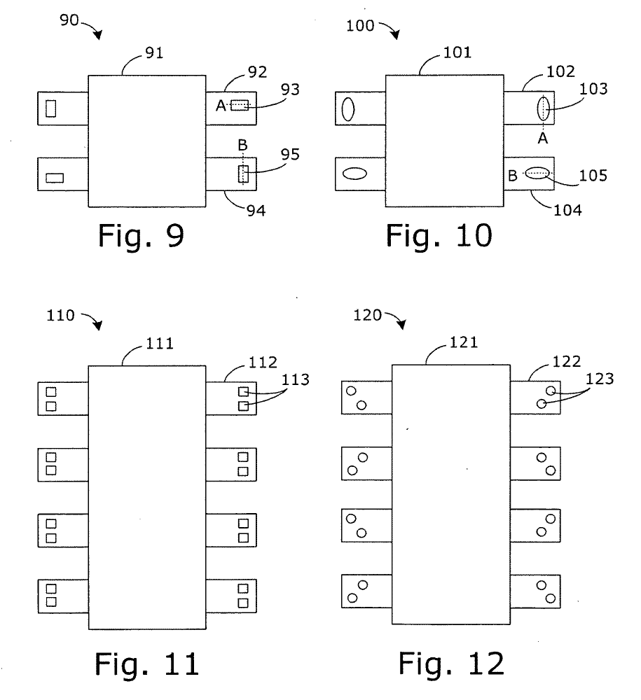

With reference to FIG. 9, a surface mount component 90 may include a housing 91 and one or more leads 92 extending from the housing. The one or more leads 92 may define respective voids 93 through respective ends of the one or more leads 92. For example, the one or more leads 92 may define a through-hole 93 at respective ends of the one or more leads 92. In some embodiments of the invention, the one or more leads 92 may comprise at least a first lead 92 defining a first through hole 93 having a first shape which is longer along a first axis A of the first shape as compared to a second axis of the first shape, and a second lead 94 defining a second through hole 95 having a second shape which is longer along a first axis B of the second shape as compared to a second axis of the second shape, wherein the first axis A of the first shape is transverse to the first axis B of the second shape. For example, the first axis A may be orthogonal to the first axis B. For example, a rectangular hole may be punched through each of the leads. Without being limited to theory of operation, it is believed that providing different orientations for the voids (e.g. holes 93 and 95) may advantageously provide a type of interlock which may increase the solder joint strength with respect to forces applied to the surface mount component from different orientations.

With reference to FIG. 10, a surface mount component 100 may include a housing 101 and one or more leads 102 extending from the housing. The one or more leads 102 may define respective voids 103 through respective ends of the one or more leads 102. For example, the one or more leads 102 may define a through-hole 103 at respective ends of the one or more leads 102. In some embodiments of the invention, the one or more leads 102 may comprise at least a first lead 102 defining a first through hole 103 having a first shape which is longer along a first axis A of the first shape as compared to a second axis of the first shape, and a second lead 104 defining a second through hole 105 having a second shape which is longer along a first axis B of the second shape as compared to a second axis of the second shape, wherein the first axis A of the first shape is transverse to the first axis B of the second shape. For example, the first axis A may be orthogonal to the first axis B. For example, an oval hole may be drilled, punched, machined, or otherwise provided through each of the leads.

With reference to FIG. 11, a surface mount component 110 may include a housing 111 and one or more leads 112 extending from the housing. The one or more leads 112 may define respective voids 113 through respective ends of the one or more leads 112. For example, the one or more leads 112 may define a through-hole 113 at respective ends of the one or more leads 112. In some embodiments of the invention, the one or more leads 112 may define a plurality of through-holes 113 at respective ends of the one or more leads 112.

With reference to FIG. 12, a surface mount component 120 may include a housing 121 and one or more leads 122 extending from the housing. The one or more leads 122 may define respective voids 123 through respective ends of the one or more leads 122. For example, the one or more leads 122 may define a through-hole 123 at respective ends of the one or more leads 122. In some embodiments of the invention, the one or more leads 122 may define a plurality of through-holes 123 at respective ends of the one or more leads 122.

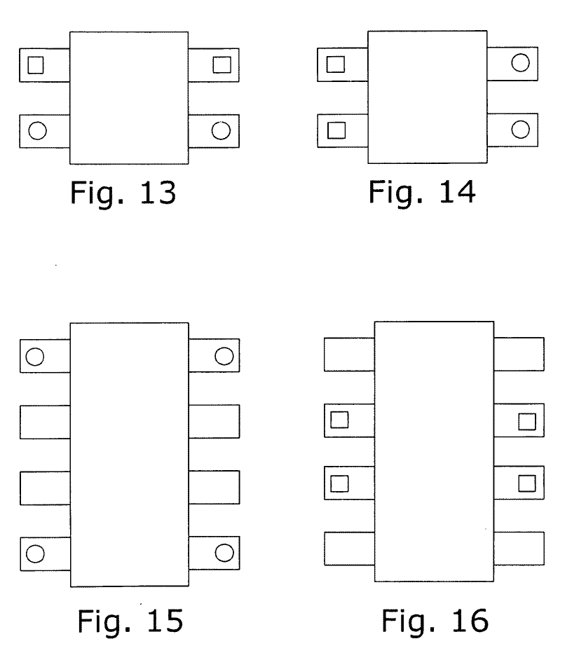

With reference to FIGS. 13 and 14, in accordance with some embodiments of the invention a surface mount component may include a variety of shapes of voids in the respective leads (e.g. a combination of round and square holes). With reference to FIGS. 15 and 16, in accordance with some embodiments of the invention a surface mount component may include voids on fewer than all the leads. For example, a surface mount component may include voids on just the corner leads (e.g. FIG. 15) or just the interior leads (e.g. FIG. 16). Numerous other varieties and combinations of features described herein are considered to be within the spirit and scope of the invention.

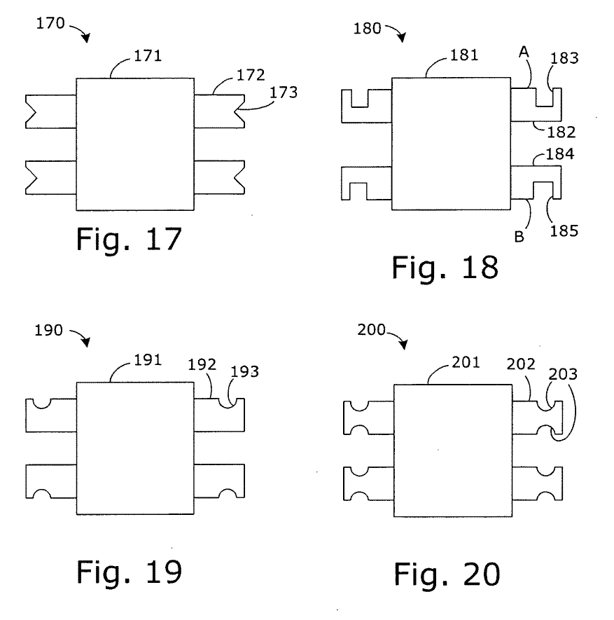

With reference to FIG. 17, a surface mount component 170 may include a housing 171 and one or more leads 172 extending from the housing. The one or more leads 172 may define respective voids 173 through respective ends of the one or more leads 172. For example, the one or more leads 172 may define a notch 173 at respective ends of the one or more leads 172. For example, a v-shaped notch 173 may be cut, punched, machined or otherwise provided at the ends of each of the leads 172.

With reference to FIG. 18, a surface mount component 180 may include a housing 181 and one or more leads 182 extending from the housing. The one or more leads 182 may define respective voids 183 through respective ends of the one or more leads 182. For example, the one or more leads 182 may define a notch 183 at respective ends of the one or more leads 182. For example, a rectangular or square notch 183 may be cut, punched, machined or otherwise provided at the ends of each of the leads 182. In some embodiments of the invention, the one or more leads may comprise at least a first lead 182 defining a first notch 183 having a first position which is along an first edge A of the first lead 182, and a second lead 184 on a same side of the surface mount component 180 as the first lead 182, the second lead 184 defining a second notch 185 having a second position which is along a different edge B of the second lead 184 as compared to the first edge A of the first lead 182. Without being limited to theory of operation, it is believed that providing different orientations for the voids (e.g. notches 183 and 185) may advantageously provide a type of interlock which may increase the solder joint strength with respect to forces applied to the surface mount component from different orientations.

With reference to FIG. 19, a surface mount component 190 may include a housing 191 and one or more leads 192 extending from the housing. The one or more leads 192 may define respective voids 193 through respective ends of the one or more leads 192. For example, the one or more leads 192 may define a notch 193 at respective ends of the one or more leads 192. For example, a round or oval notch 193 may be drilled, cut, punched, machined or otherwise provided at the ends of each of the leads 192.

With reference to FIG. 20, a surface mount component 200 may include a housing 201 and one or more leads 202 extending from the housing. The one or more leads 202 may define respective voids 203 through respective ends of the one or more leads 202. For example, the one or more leads 202 may define a notch 203 at respective ends of the one or more leads 202. In some embodiments of the invention, the one or more leads 202 may define a plurality of notches 203 at respective ends of the one or more leads 202.

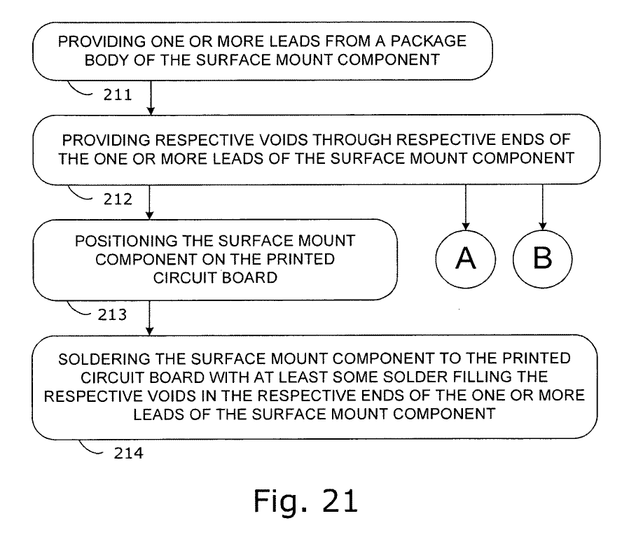

With reference to FIG. 21, in accordance with some embodiments of the invention, a method of mounting a surface mount component to a printed circuit board may include providing one or more leads from a package body of the surface mount component (e.g. at block 211), providing respective voids through respective ends of. the one or more leads of the surface mount component (e.g. at block 212), positioning the surface mount component on the printed circuit board (e.g. at block 213), and soldering the surface mount component to the printed circuit board with at least some solder filling the respective voids in the respective ends of the one or more leads of the surface mount component (e.g. at block 214).

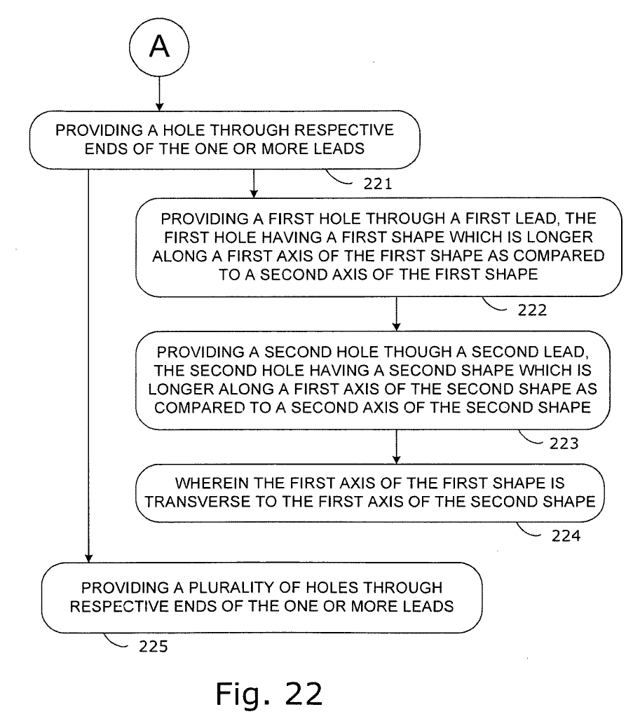

With reference to FIG. 22, in some embodiments of the invention, providing respective voids through respective ends of the one or more leads of the surface mount component may include providing a hole through respective ends of the one or more leads (e.g. at block 221). For example, providing a hole through respective ends of the one or more leads may include providing a first hole through a first lead, the first hole having a first shape which is longer along a first axis of the first shape as compared to a second axis of the first shape (e.g. at block 222), and providing a second hole though a second lead, the a second hole having a second shape which is longer along a first axis of the second shape as compared to a second axis of the second shape (e.g. at block 223). For example, the first axis of the first shape may be transverse to the first axis of the second shape (e.g. at block 224). In some embodiments of the invention, providing a hole through respective ends of the one or more leads may include providing a plurality of holes through respective ends of the one or more leads (e.g. at block 225).

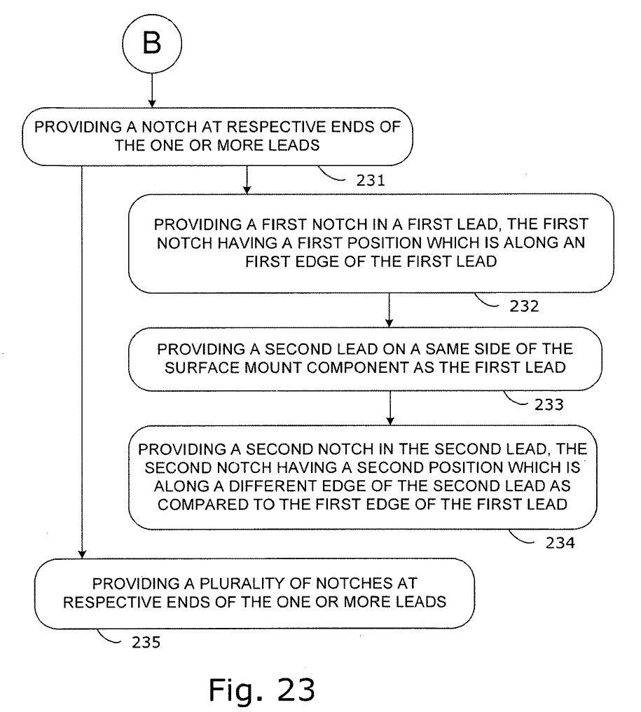

With reference to FIG. 23, in some embodiments of the invention, providing respective voids through respective ends of the one or more leads of the surface mount component may include providing a notch at respective ends of the one or more leads (e.g. at block 231). For example, providing a notch at respective ends of the one or more leads may include providing a first notch in a first lead, the first notch having a first position which is along an first edge of the first lead (e.g. at block 232), providing a second lead on a same side of the surface mount component as the first lead (e.g. at block 233), and providing a second notch in the second lead, the second notch having a second position which is along a different edge of the second lead as compared to the first edge of the first lead (e.g. at block 234). In some embodiments of the invention, providing a notch at respective ends of the one or more leads may include providing a plurality of notches at respective ends of the one or more leads (e.g. at block 235).

Without being limited to theory of operation, it is believed that some embodiments of the invention may advantageously provide a self forming and self containing anchoring pin or rivet to provide additional solder joint strength to a package with a footed lead frame to the PCB. Another potential advantage of some embodiments of the invention is that the voids may be formed in the lead frames at relatively low cost and low manufacturing complexity. Another potential advantage of some embodiments of the invention is that solder joint strength may be improved with little or no production manufacturing changes to the assembly line. Another potential advantage of some embodiments of the invention is that solder joint strength may be improved while allowing the same lead frame pin pitch (e.g. width and space). Another potential advantage of some embodiments of the invention is that a stronger solder joint may improve the likelihood of passing qualification stresses (e.g. from −40 C to 85 C) and may improve reliability under normal environmental usage.

Without being limited to theory of operation, it is believed that some embodiments of the invention may advantageously increase a device's ruggedness. For example, some embodiments of the invention maybe particularly advantages for small hand held devices that may need to pass temperature (−40 C to 85 C) cycling stresses as well as rigorous or harsh handing environments including drop testing of devices, shock testing of devices, and/or vibration testing of devices.

Without being limited to theory of operation, it is believed that some embodiments of the invention may advantageously strengthen the solder joint by increasing the surface contact area between the solder and the lead. For example, some embodiments of the invention may almost double the surface area. For example, the surface area may include the solder area at the lead top, the solder area for the connecting solder pin, and the solder area at the PCB. The sum of these areas may increase the overall contact area and provide a stronger solder joint.

Without being limited to theory of operation, it is believed that some embodiments of the invention may advantageously add tensile strength to the solder joint. Without being limited to theory of operation, it is believed that some embodiments of the invention may advantageously redirects potential cracking through a longer path.

The foregoing and other aspects of the invention are achieved individually and in combination. The invention should not be construed as requiring two or more of such aspects unless expressly required by a particular claim. Moreover, while the invention has been described in connection with what is presently considered to be the preferred examples, it is to be understood that the invention is not limited to the disclosed examples, but on the contrary, is intended to cover various modifications and equivalent arrangements included within the spirit and the scope of the invention.

What is claimed is:

1. A surface mount component, comprising:
a housing; and
one or more leads extending from the housing, wherein the one or more leads define respective voids through respective ends of the one or more leads.

2. The surface mount component of claim 1, wherein the one or more leads define a through-hole at respective ends of the one or more leads.

3. The surface mount component of claim 2, wherein the one or more leads comprise at least:
a first lead defining a first through hole having a first shape which is longer along a first axis of the first shape as compared to a second axis of the first shape; and
a second lead defining a second through hole having a second shape which is longer along a first axis of the second shape as compared to a second axis of the second shape,
wherein the first axis of the first shape is transverse to the first axis of the second shape.

4. The surface mount component of claim 2, wherein the one or more leads define a plurality of through-holes at respective ends of the one or more leads.

5. The surface mount component of claim 1, wherein the one or more leads define a notch at respective ends of the one or more leads.

6. The surface mount component of claim 5, wherein the one or more leads comprise at least:
a first lead defining a first notch having a first position which is along an first edge of the first lead; and
a second lead on a same side of the surface mount component as the first lead, the second lead defining a second notch having a second position which is along a different edge of the second lead as compared to the first edge of the first lead.

7. The surface mount component of claim 5, wherein the one or more leads define a plurality of notches at respective ends of the one or more leads.

8. A method of mounting a surface mount component to a printed circuit board, comprising:
providing one or more leads from a package body of the surface mount component;
providing respective voids through respective ends of the one or more leads of the surface mount component;
positioning the surface mount component on the printed circuit board; and
soldering the surface mount component to the printed circuit board with at least some solder filling the respective voids in the respective ends of the one or more leads of the surface mount component.

9. The method of claim 8, wherein providing respective voids through respective ends of the one or more leads of the surface mount component comprises:
providing a hole through respective ends of the one or more leads.

10. The method of claim 9, wherein providing a hole through respective ends of the one or more leads comprises:
providing a first hole through a first lead, the first hole having a first shape which is longer along a first axis of the first shape as compared to a second axis of the first shape; and
providing a second hole though a second lead, the second hole having a second shape which is longer along a first axis of the second shape as compared to a second axis of the second shape,
wherein the first axis of the first shape is transverse to the first axis of the second shape.

11. The method of claim 9, wherein providing a hole through respective ends of the one or more leads comprises:
providing a plurality of holes through respective ends of the one or more leads.

12. The method of claim 8, wherein providing respective voids through respective ends of the one or more leads of the surface mount component comprises:
providing a notch at respective ends of the one or more leads.

13. The method of claim 12, wherein providing a notch at respective ends of the one or more leads comprises:
providing a first notch in a first lead, the first notch having a first position which is along an first edge of the first lead; and
providing a second lead on a same side of the surface mount component as the first lead;
providing a second notch in the second lead, the second notch having a second position which is along a different edge of the second lead as compared to the first edge of the first lead.

14. The method of claim 12, wherein providing a notch at respective ends of the one or more leads comprises:
providing a plurality of notches at respective ends of the one or more leads.

15. An electronic system, comprising:
a printed circuit board;
a surface mount component mounted on the printed circuit board, wherein the surface mount component includes:
a housing,
one or more leads extending from the housing, wherein the one or more leads define respective voids through respective ends of the one or more leads; and
a fixing material disposed through the respective voids of the one or more leads to secure the surface mount component to the printed circuit board.

16. The electronic system of claim 15, wherein the one or more leads define a through-hole at respective ends of the one or more leads.

17. The electronic system of claim 16, wherein the one or more leads comprise at least:
a first lead defining a first through hole having a first shape which is longer along a first axis of the first shape as compared to a second axis of the first shape; and
a second lead defining a second through hole having a second shape which is longer along a first axis of the second shape as compared to a second axis of the second shape,
wherein the first axis of the first shape is transverse to the first axis of the second shape.

18. The electronic system of claim 16, wherein the one or more leads define a plurality of through-holes at respective ends of the one or more leads.

19. The electronic system of claim 15, wherein the one or more leads define a notch at respective ends of the one or more leads.

20. The electronic system of claim 19, wherein the one or more leads comprise at least:
a first lead defining a first notch having a first position which is along an first edge of the first lead; and
a second lead on a same side of the surface mount component as the first lead, the second lead defining a second notch having a second position which is along a different edge of the second lead as compared to the first edge of the first lead.

21. The electronic system of claim 19, wherein the one or more leads define a plurality of notches at respective ends of the one or more leads.

22. The electronic system of claim 15, wherein the fixing material comprises solder.

23. The electronic system of claim 22, wherein the solder forms a pin which helps secure the surface mount component to the printed circuit board.
